(19) United States
(12) Patent Application Publication
(10) Pub. No.: US 2013/0062631 A1
(43) Pub. Date: Mar. 14, 2013

(54) LIGHT EMITTING STRUCTURE, LIGHT EMITTING MODULE, AND LIGHT EMITTING DEVICE

(71) Applicant: CHIA-CHI LIU, Taipei City (TW)

(72) Inventor: CHIA-CHI LIU, Taipei City (TW)

(73) Assignee: LUSTROUS GREEN TECHNOLOGY OF LIGHTING, NEW TAIPEI CITY (TW)

(21) Appl. No.: 13/231,915

(22) Filed: Sep. 13, 2011

(51) Int. Cl. H01L 33/52

(52) U.S. Cl. 257/88; 257/E33.059

(57) ABSTRACT

A light emitting module includes a carrier unit, a substrate unit, and a light emitting unit. The carrier unit includes at least one carrier body, and the carrier body has a mounting portion. The substrate unit includes at least one bendable substrate. The bendable substrate includes a plurality of substrate portions and a plurality of bending portions, the substrate portions are disposed on the mounting portion of the carrier body, and each bending portion is disposed between every two corresponding substrate portions. The light emitting unit includes a plurality of light emitting groups respectively disposed on the substrate portions, and each light emitting group includes at least one light emitting element electrically connected to each corresponding substrate portion. Because the substrate portions can be disposed on different planes after bending the substrate portions, thus light sources respectively generated by the light emitting elements can be projected toward different directions.

### BACKGROUND OF THE INVENTION

1. Field of the Invention

The instant disclosure relates to a light emitting structure, a light emitting module, and a light emitting device, and more particularly, to a light emitting structure using at least one bendable substrate, a light emitting module using at least one bendable substrate, and a light emitting device using at least one bendable substrate.

2. Description of Related Art

The invention of the lamp greatly changed the style of building construction and the lifestyle of human beings, allowing people to work during the night. Traditional lighting devices such as lamps that adopt incandescent bulbs, fluorescent bulbs, or power-saving bulbs have been generally well-developed and used intensively for indoor illumination.

Moreover, compared to the newly developed light-emitting-diode (LED) lamps, these traditional lamps have the disadvantages of quick attenuation, high power consumption, high heat generation, short service life, high fragility, and being not recyclable. Thus, various high-powered LED lamps are created to replace the traditional lighting devices.

### SUMMARY OF THE INVENTION

One aspect of the instant disclosure relates to a light emitting structure having at least one bendable substrate, a light emitting module having at least one bendable substrate, and a light emitting device having at least one bendable substrate.

One of the embodiments of the instant disclosure provides a light emitting structure, comprising: a substrate unit and a light emitting unit. The substrate unit includes at least one bendable substrate, wherein the at least one bendable substrate includes a plurality of substrate portions and a plurality of bending portions, and each bending portion is disposed between every two corresponding substrate portions. The light emitting unit includes a plurality of light emitting groups respectively disposed on the substrate portions, wherein each light emitting group includes at least one light emitting element electrically connected to each corresponding substrate portion.

Another one of the embodiments of the instant disclosure provides a light emitting module, comprising: a carrier unit, a substrate unit, and a light emitting unit. The carrier unit includes at least one carrier body, wherein the at least one carrier body has a mounting portion. The substrate unit includes at least one bendable substrate, wherein the at least one bendable substrate includes a plurality of substrate portions and a plurality of bending portions, the substrate portions are disposed on the mounting portion of the at least one carrier body, and each bending portion is disposed between every two corresponding substrate portions. The light emitting unit includes a plurality of light emitting groups respectively disposed on the substrate portions, wherein each light emitting group includes at least one light emitting element electrically connected to each corresponding substrate portion.

Another one of the embodiments of the instant disclosure provides a light emitting device, comprising: a base unit, a carrier unit, a substrate unit, a light emitting unit, and a lamp cover unit. The base unit includes at least one electrical connection element disposed on the bottom side thereof. The carrier unit includes at least one carrier body disposed on the top side of the base unit, wherein the at least one carrier body has a mounting portion. The substrate unit includes at least one bendable substrate electrically connected to the at least one electrical connection element, wherein the at least one bendable substrate includes a plurality of substrate portions and a plurality of bending portions, the substrate portions are disposed on the mounting portion of the at least one carrier body, and each bending portion is disposed between every two corresponding substrate portions. The light emitting unit includes a plurality of light emitting groups respectively disposed on the substrate portions, wherein each light emitting group includes at least one light emitting element electrically connected to each corresponding substrate portion. The lamp cover unit includes a light permitting cover mated with the base unit to protect the substrate unit and the light emitting unit.

To further understand the techniques, means and effects of the instant disclosure applied for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1A shows a top, schematic view of the light emitting structure before bending the substrate unit according to the first embodiment of the instant disclosure;

FIG. 1B shows a lateral, cross-sectional, schematic view of the light emitting structure before bending the substrate unit according to the first embodiment of the instant disclosure;

FIG. 1C shows a lateral, cross-sectional, exploded, schematic view of the light emitting module after bending the substrate unit according to the first embodiment of the instant disclosure;

FIG. 1D shows a lateral, cross-sectional, assembled, schematic view of the light emitting module after bending the substrate unit according to the first embodiment of the instant disclosure;

FIG. 1E shows a partial, cross-sectional, schematic view of the light emitting device according to the first embodiment of the instant disclosure;

FIG. 2 shows a top, schematic view of the light emitting structure before bending the substrate unit according to the second embodiment of the instant disclosure;

FIG. 3 shows a top, schematic view of the light emitting structure before bending the substrate unit according to the third embodiment of the instant disclosure;

FIG. 4A shows a top, schematic view of the light emitting structure before bending the substrate unit according to the fourth embodiment of the instant disclosure;

FIG. 4B shows a lateral, cross-sectional, schematic view of the light emitting structure before bending the substrate unit according to the fourth embodiment of the instant disclosure;

FIG. 4C shows a lateral, cross-sectional, exploded, schematic view of the light emitting module after bending the substrate unit according to the fourth embodiment of the instant disclosure;

FIG. 4D shows a lateral, cross-sectional, assembled, schematic view of the light emitting module after bending the substrate unit according to the fourth embodiment of the instant disclosure;

FIG. 4E shows a partial, cross-sectional, schematic view of the light emitting device according to the fourth embodiment of the instant disclosure; and

FIG. 5 shows a lateral, cross-sectional, schematic view of the light emitting unit disposed on the substrate unit according to the fifth embodiment of the instant disclosure.

### DETAILED DESCRIPTION OF THE PREFERRED EMBODIMENTS

### First Embodiment

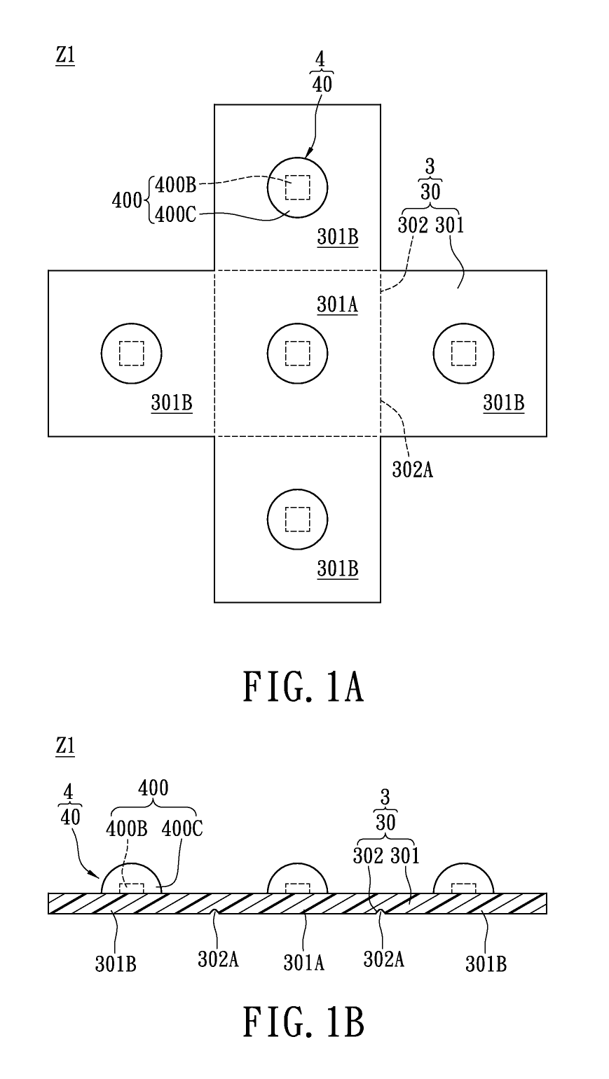

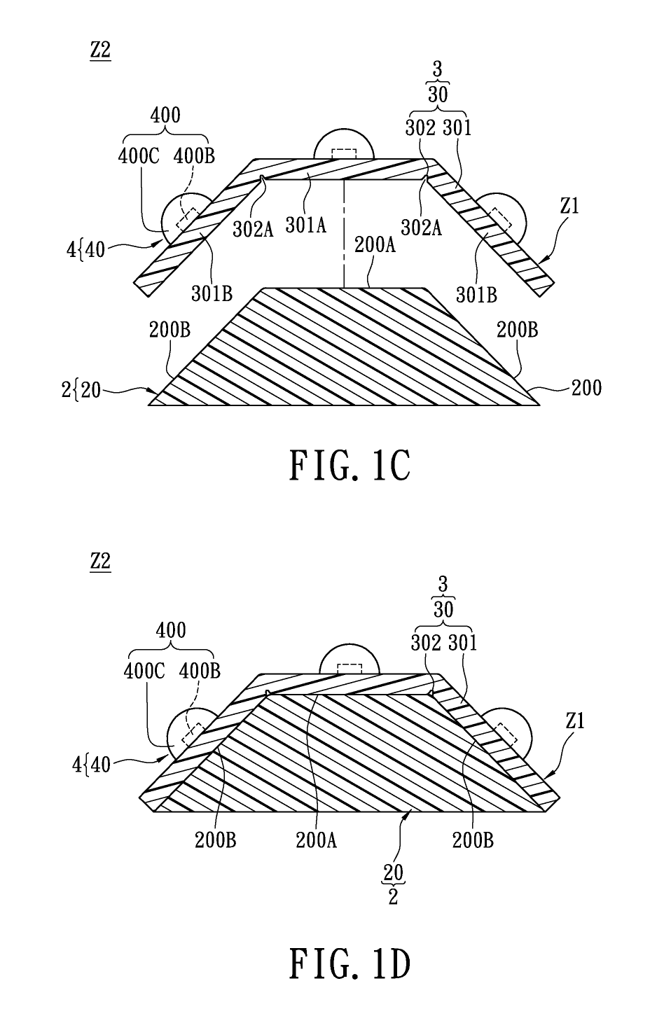

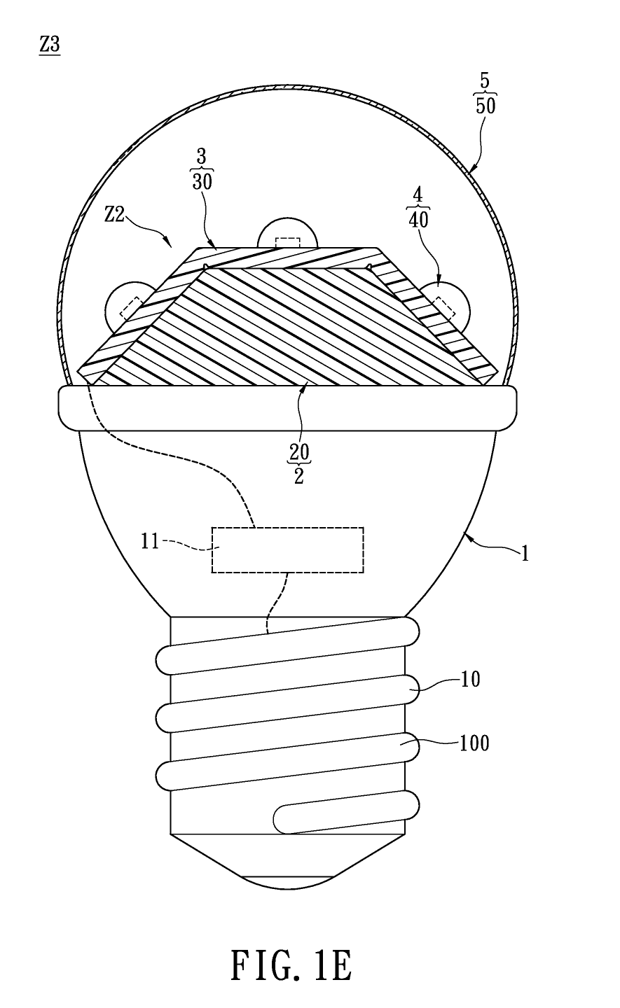

Referring to FIGS. 1A and 1B, where FIG. 1A shows a top, schematic view of the light emitting structure before the bending process, and FIG. 1B shows a lateral, cross-sectional, schematic view of the light emitting structure before the bending process. The first embodiment of instant disclosure provides a light emitting structure Z1, comprising: a substrate unit 3 and a light emitting unit 4.

Referring to FIGS. 1A and 1B again, the substrate unit 3 includes at least one bendable substrate 30. The at least one bendable substrate 30 includes a plurality of substrate portions 301 and a plurality of bending portions 302, and each bending portion 302 is disposed between every two corresponding substrate portions 301.

For example, the at least one bendable substrate 30 may be any type of bendable circuit substrate. One of the substrate portions 301 may be a middle substrate portion 301A, the other substrate portions 301 may be surrounding substrate portions 301B surrounding the middle substrate portion 301A, and each surrounding substrate portion 301B can be connected to the middle substrate portion 301A and outwardly extended from the middle substrate portion 301A. Because the middle substrate portion 301A may be a square having four lateral sides, four surrounding substrate portions 301B can be respectively connected to the four lateral sides of the middle substrate portion 301A, and each bending portion 302 can be disposed between the middle substrate portion 301A and each corresponding surrounding substrate portion 301B. In addition, each bending portion 302 has at least one cutting groove 302A (such as a V-shaped cutting groove) formed between every two corresponding substrate portions 301, and the at least one cutting groove 302A is formed on the bottom side of the at least one bendable substrate 30. However, the bending portions 302 used in the first embodiment is merely an example and is not meant to limit the instant disclosure.

Referring to FIGS. 1A and 1B again, the light emitting unit 4 includes a plurality of light emitting groups 40 respectively disposed on the substrate portions 301. Each light emitting group 40 includes at least one light emitting element 400 electrically connected to each corresponding substrate portion 301.

For example, each light emitting element 400 includes a LED chip 400B (such as a bare LED chip) disposed on the corresponding substrate portion 301 and a package resin body 400C disposed on the corresponding substrate portion 301 to cover the LED chip 400B. With regard to each light emitting element 400, the LED chip 400B can be disposed on the corresponding substrate portion 301 and electrically connected to the corresponding substrate portion 301 by a COB (Chip On Board) method, and then the package resin body 400C can be used to cover the LED chip 400B in order to protect the LED chip 400B. Moreover, when the LED chip 400B is a blue LED chip and the package resin body 400C is a phosphor resin body, the blue light source generated by the blue LED chip can be transformed into a white light source through the phosphor resin body. However, the light emitting unit 4 used in the first embodiment is merely an example and is not meant to limit the instant disclosure.

Referring to FIGS. 1C and 1D, where FIG. 1C shows a lateral, cross-sectional, exploded, schematic view of the light emitting module after the light emitting structure has been bent, and FIG. 1D shows a lateral, cross-sectional, assembled, schematic view of the light emitting module after the light emitting structure has been bent. The first embodiment of instant disclosure provides a light emitting module Z2 using the light emitting structure Z1, comprising: a carrier unit 2, a substrate unit 3, and a light emitting unit 4. In addition, the carrier unit 2 includes at least one carrier body 20. The at least one carrier body 20 has a mounting portion 200, and the substrate portions 301 are disposed on the mounting portion 200 of the at least one carrier body 20.

Before each surrounding substrate portion 301B is bent from the middle substrate portion 301A (as shown in FIG. 1B), the middle substrate portion 301A and the surrounding substrate portions 301B are arranged coplanarly. After each surrounding substrate portion 301B is bent from the middle substrate portion 301A through each corresponding bending portion 302 (such as the cutting groove 302A) (as shown in FIG. 1C), each surrounding substrate portion 301B is still connected to the middle substrate portion 301A and is obliquely downwardly extended from the middle substrate portion 301A. Hence, the middle substrate portion 301A and the surrounding substrate portions 301B can be disposed on different planes after bending the surrounding substrate portions 301B from the middle substrate portion 301A, thus light sources respectively generated by the light emitting elements 400 can be projected toward different directions.

For example, the mounting portion 200 has at least one top mounting surface 200A disposed on the topmost side of the at least one carrier body 20 and a plurality of surrounding mounting surfaces 200B surrounding the periphery of the at least one carrier body 20, and each surrounding mounting surface 200B is connected to the at least one top mounting surface 200A and obliquely downwardly extended from the at least one top mounting surface 200A. In addition, one of the substrate portions 301 can be disposed on the at least one top mounting surface 200A, and the other substrate portions 301 can be bent along the corresponding bending portions 302 and respectively disposed on the surrounding mounting surfaces 200B. In other words, referring to FIG. 1D, the middle substrate portion 301A can be disposed on the at least one top mounting surface 200A, and the surrounding substrate portions 301B can be bent along the corresponding bending portions 302 and respectively disposed on the surrounding mounting surfaces 200B, thus light sources respectively generated by the light emitting elements 400 can be projected toward different directions in order to increase the illumination range.

Referring to FIG. 1E, where the first embodiment of instant disclosure provides a light emitting device Z3 using the light emitting module Z2, comprising: a base unit 1, a carrier unit 2, a substrate unit 3, a light emitting unit 4, and a lamp cover unit 5. In addition, the base unit 1 includes at least one electrical connection element 10 disposed on the bottom side thereof. The carrier unit 2 includes at least one carrier body 20 disposed on the top side of the base unit 1. The substrate unit 3 includes at least one bendable substrate 30 electrically connected to the at least one electrical connection element 10. The light emitting unit 4 includes a plurality of light emitting groups 40 disposed on the at least one bendable substrate 30. The lamp cover unit 5 includes a light permitting cover 50 mated with the base unit 1 to protect the substrate unit 3 and the light emitting unit 4.

For example, the at least one electrical connection element 10 may be an electrical connector having a threaded body 100 formed on the external surface of the electrical connector, thus the at least one electrical connection element 10 of the light emitting device Z3 can be rotatably inserted into a power socket (not shown) to obtain power supply. In addition, the base unit 1 further includes a drive IC 11 disposed therein, and the drive IC 11 can be electrically connected between the at least one electrical connection element 10 and the light emitting unit 4 to transform the voltage from AC (alternating current) into DC (Direct current), thus the instant disclosure can provide DC for the light emitting unit 4.

### Second Embodiment

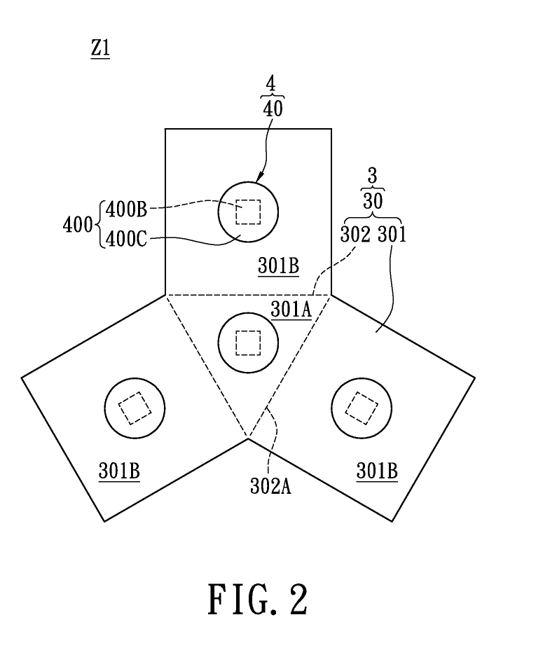

Referring to FIG. 2, where the second embodiment of instant disclosure provides a light emitting structure Z1, comprising: a substrate unit 3 and a light emitting unit 4. Comparing FIG. 2 with FIG. 1A, the difference between the second embodiment and the first embodiment is that: in the second embodiment, because the middle substrate portion 301A may be a triangle having three lateral sides, there are three surrounding substrate portions 301B that can be respectively connected to the three lateral sides of the middle substrate portion 301A, and each bending portion 302 (such as the cutting groove 302A) can be disposed between the middle substrate portion 301A and each corresponding surrounding substrate portion 301B. In other words, when the middle substrate portion 301A has N (N is a positive integer) lateral sides, there are N surrounding substrate portions 301B that can be respectively connected to the N lateral sides of the middle substrate portion 301A. However, the shape (or the number of the lateral sides) of the middle substrate portion 301A and the number of the surrounding substrate portions 301B in the second embodiment are merely an example and are not meant to limit the instant disclosure.

### Third Embodiment

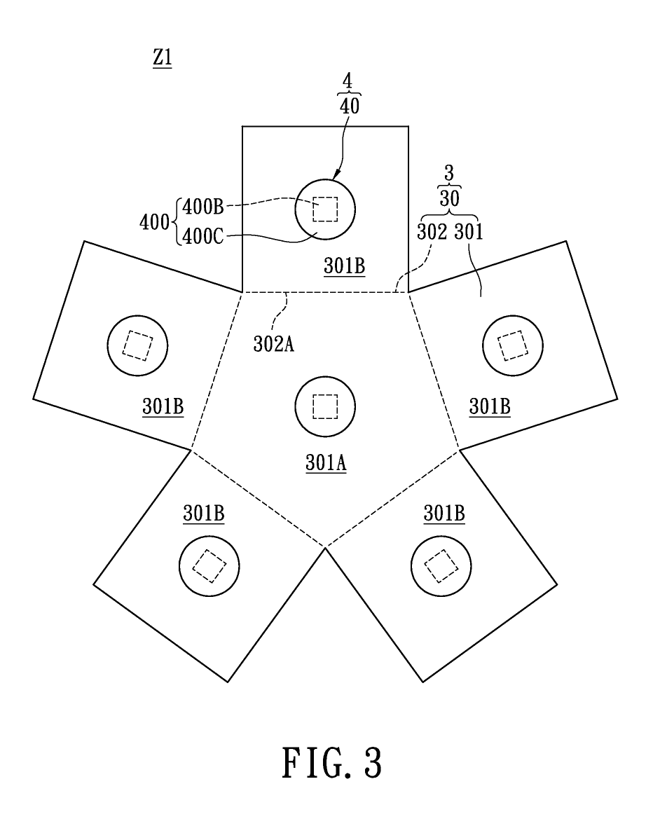

Referring to FIG. 3, where the third embodiment of instant disclosure provides a light emitting structure Z1, comprising: a substrate unit 3 and a light emitting unit 4. Comparing FIG. 3 with FIG. 1A, the difference between the third embodiment and the first embodiment is that: in the third embodiment, because the middle substrate portion 301A may be a pentagon having five lateral sides, there are five surrounding substrate portions 301B that can be respectively connected to the five lateral sides of the middle substrate portion 301A, and each bending portion 302 (such as the cutting groove 302A) can be disposed between the middle substrate portion 301A and each corresponding surrounding substrate portion 301B. In other words, when the middle substrate portion 301A has N (N is a positive integer) lateral sides, there are N surrounding substrate portions 301B that can be respectively connected to the N lateral sides of the middle substrate portion 301A. However, the shape (or the number of the lateral sides) of the middle substrate portion 301A and the number of the surrounding substrate portions 301B in the third embodiment are merely an example and are not meant to limit the instant disclosure.

### Fourth Embodiment

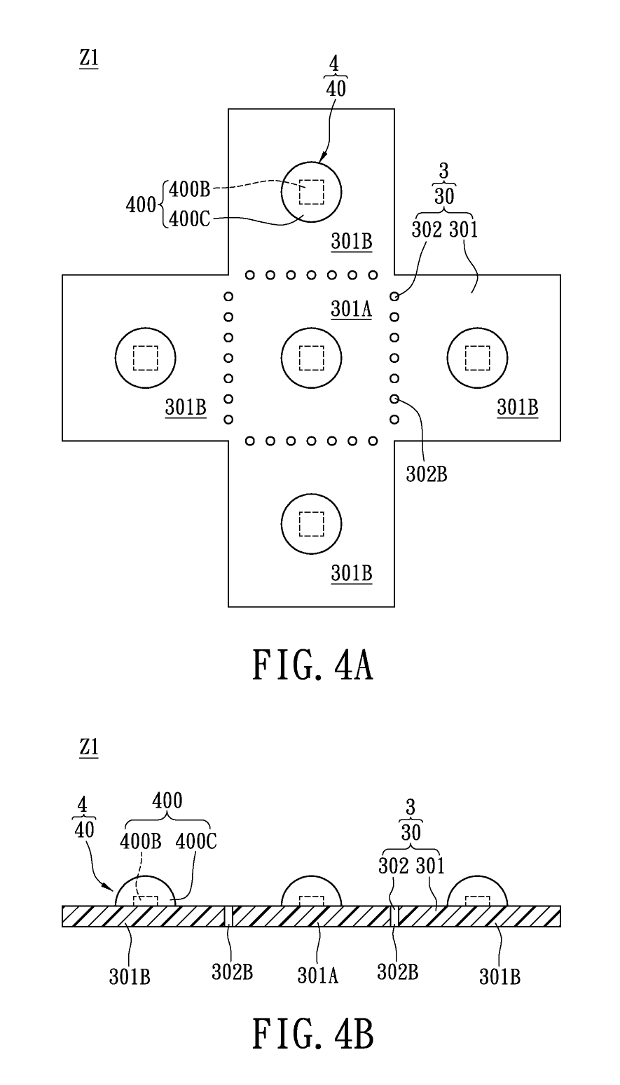

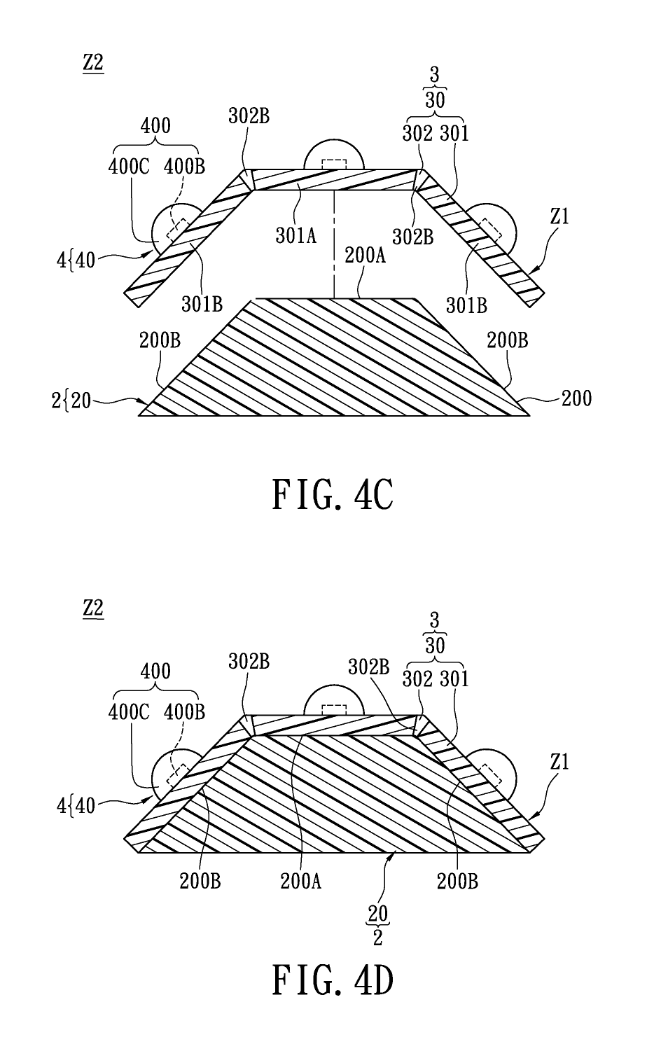

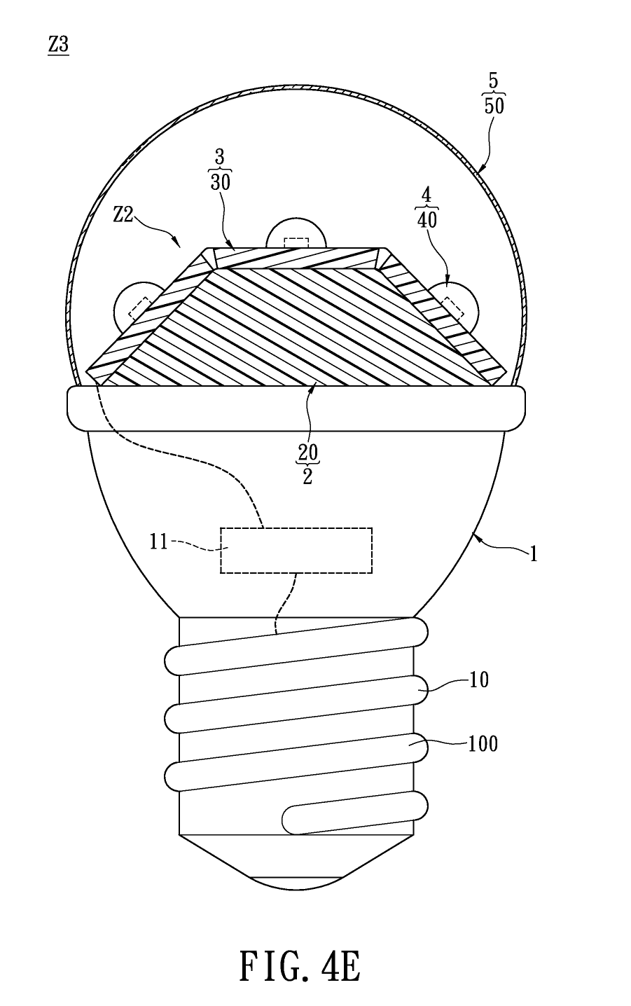

Referring to FIGS. 4A and 4B, where FIG. 4A shows a top, schematic view of the light emitting structure before the bending process, and FIG. 4B shows a lateral, cross-sectional, schematic view of the light emitting structure before the bending process. The fourth embodiment of instant disclosure provides a light emitting structure Z1, comprising: a substrate unit 3 and a light emitting unit 4.

Referring to FIGS. 4A and 4B again, the substrate unit 3 includes at least one bendable substrate 30. The at least one bendable substrate 30 includes a plurality of substrate portions 301 and a plurality of bending portions 302, and each bending portion 302 is disposed between every two corresponding substrate portions 301.

For example, the at least one bendable substrate 30 may be any type of bendable circuit substrate. One of the substrate portions 301 may be a middle substrate portion 301A, the other substrate portions 301 may be surrounding substrate portions 301B surrounding the middle substrate portion 301A, and each surrounding substrate portion 301B can be connected to the middle substrate portion 301A and outwardly extended from the middle substrate portion 301A. Because the middle substrate portion 301A may be a square having four lateral sides, there are four surrounding substrate portions 301B that can be respectively connected to the four lateral sides of the middle substrate portion 301A, and each bending portion 302 can be disposed between the middle substrate portion 301A and each corresponding surrounding substrate portion 301B. In addition, each bending portion 302 has a plurality of through holes 302B formed between every two corresponding substrate portions 301, and each through hole 302B passes through the at least one bendable substrate 30. However, the bending portions 302 used in the fourth embodiment is merely an example and is not meant to limit the instant disclosure.

Referring to FIGS. 4A and 4B again, the light emitting unit 4 includes a plurality of light emitting groups 40 respectively disposed on the substrate portions 301. Each light emitting group 40 includes at least one light emitting element 400 electrically connected to each corresponding substrate portion 301.

For example, each light emitting element 400 includes a LED chip 400B (such as a bare LED chip) disposed on the corresponding substrate portion 301 and a package resin body 400C disposed on the corresponding substrate portion 301 to cover the LED chip 400B. With regard to each light emitting element 400, the LED chip 400B can be disposed on the corresponding substrate portion 301 and electrically connected to the corresponding substrate portion 301 by a COB (Chip On Board) method, and then the package resin body 400C can be used to cover the LED chip 400B in order to protect the LED chip 400B. Moreover, when the LED chip 400B is a blue LED chip and the package resin body 400C is a phosphor resin body, the blue light source generated by the blue LED chip can be transformed into a white light source through the phosphor resin body. However, the light emitting unit 4 used in the fourth embodiment is merely an example and is not meant to limit the instant disclosure.

Referring to FIGS. 4C and 4D, where FIG. 4C shows a lateral, cross-sectional, exploded, schematic view of the light emitting module after the light emitting structure has been bent, and FIG. 4D shows a lateral, cross-sectional, assembled, schematic view of the light emitting module after the light emitting structure has been bent. The fourth embodiment of instant disclosure provides a light emitting module Z2 using the light emitting structure Z1, comprising: a carrier unit 2, a substrate unit 3, and a light emitting unit 4. In addition, the carrier unit 2 includes at least one carrier body 20. The at least one carrier body 20 has a mounting portion 200, and the substrate portions 301 are disposed on the mounting portion 200 of the at least one carrier body 20.

Before each surrounding substrate portion 301B is bent from the middle substrate portion 301A (as shown in FIG. 4B), the middle substrate portion 301A and the surrounding substrate portions 301B are arranged coplanarly. After each surrounding substrate portion 301B is bent from the middle substrate portion 301A through each corresponding bending portion 302 (such as the through holes 302B) (as shown in FIG. 4C), each surrounding substrate portion 301B is still connected to the middle substrate portion 301A and is obliquely downwardly extended from the middle substrate portion 301A. Hence, the middle substrate portion 301A and the surrounding substrate portions 301B can be disposed on the different planes after bending the surrounding substrate portions 301B from the middle substrate portion 301A, thus light sources respectively generated by the light emitting elements 400 can be projected toward different directions.

For example, the mounting portion 200 has at least one top mounting surface 200A disposed on the topmost side of the at least one carrier body 20 and a plurality of surrounding mounting surfaces 200B surrounding the periphery of the at least one carrier body 20, and each surrounding mounting surface 200B is connected to the at least one top mounting surface 200A and obliquely downwardly extended from the at least one top mounting surface 200A. In addition, one of the substrate portions 301 can be disposed on the at least one top mounting surface 200A, and the other substrate portions 301 of the bent substrate unit 3 can be respectively disposed on the surrounding mounting surfaces 200B. In other words, referring to FIG. 4D, the middle substrate portion 301A can be disposed on the at least one top mounting surface 200A, and the surrounding substrate portions 301B can be bent along the corresponding bending portions 302 and respectively disposed on the surrounding mounting surfaces 200B, thus light sources respectively generated by the light emitting elements 400 can be projected toward different directions in order to increase the illumination range.

Referring to FIG. 4E, where the fourth embodiment of instant disclosure provides a light emitting device Z3 using the light emitting module Z2, comprising: a base unit 1, a carrier unit 2, a substrate unit 3, a light emitting unit 4, and the lamp cover unit 5. In addition, the base unit 1 includes at least one electrical connection element 10 disposed on the bottom side thereof. The carrier unit 2 includes at least one carrier body 20 disposed on the top side of the base unit 1. The substrate unit 3 includes at least one bendable substrate 30 electrically connected to the at least one electrical connection element 10. The light emitting unit 4 includes a plurality of light emitting groups 40 disposed on the at least one bendable substrate 30. The lamp cover unit 5 includes a light permitting cover 50 mated with the base unit 1 to protect the substrate unit 3 and the light emitting unit 4.

For example, the at least one electrical connection element 10 may be an electrical connector having a threaded body 100 formed on the external surface of the electrical connector, thus the at least one electrical connection element 10 of the light emitting device Z3 can be rotatably disposed into a power socket (not shown) to obtain power supply. In addition, the base unit 1 further includes a drive IC 11 disposed therein, and the drive IC 11 can be electrically connected between the at least one electrical connection element 10 and the light emitting unit 4 to transform the voltage from AC (alternating current) into DC (Direct current), thus the instant disclosure can provide DC for the light emitting unit 4.

### Fifth Embodiment

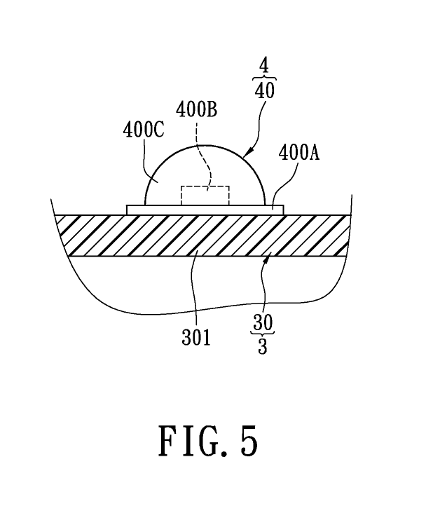

Referring to FIG. 5, the fifth embodiment of the instant disclosure provides another light emitting unit 4 including a plurality of light emitting groups 40 respectively disposed on the substrate portions 301 of the at least one bendable substrate 30, and each light emitting group 40 includes at least one light emitting element 400 electrically connected to each corresponding substrate portion 301. Comparing FIG. 5 with FIG. 1B, the difference between the fifth embodiment and the first embodiment is that: in the fifth embodiment, each light emitting element 400 includes a circuit board 400A disposed on the corresponding substrate portion 301, a LED chip 400B disposed on the circuit board 400A and electrically connected to the circuit board 400A, and a package resin body 400C disposed on the circuit board 400A to cover the LED chip 400B. In other words, each light emitting group 40 can also be disposed on the corresponding substrate portion 301 by a SMT (Surface Mounting Technology) method.

The above-mentioned descriptions merely represent the preferred embodiments of the instant disclosure, without any intention or ability to limit the scope of the instant disclosure which is fully described only within the following claims Various equivalent changes, alterations or modifications based on the claims of instant disclosure are all, consequently, viewed as being embraced by the scope of the instant disclosure.

What is claimed is:

1. A light emitting structure, comprising:
a substrate unit including at least one bendable substrate, wherein the at least one bendable substrate includes a plurality of substrate portions and a plurality of bending portions, and each bending portion is disposed between every two corresponding substrate portions; and
a light emitting unit including a plurality of light emitting groups respectively disposed on the substrate portions, wherein each light emitting group includes at least one light emitting element electrically connected to each corresponding substrate portion.

2. The light emitting structure of claim 1, wherein one of the substrate portions is a middle substrate portion, the other substrate portions are surrounding substrate portions surrounding the middle substrate portion, and each surrounding substrate portion is connected to the middle substrate portion and obliquely downwardly extended from the middle substrate portion.

3. The light emitting structure of claim 1, wherein each bending portion has at least one cutting groove formed between every two corresponding substrate portions, and the at least one cutting groove is formed on the bottom side of the at least one bendable substrate.

4. The light emitting structure of claim 1, wherein each bending portion has a plurality of through holes formed between every two corresponding substrate portions, and each through hole passes through the at least one bendable substrate.

5. The light emitting structure of claim 1, wherein each light emitting element includes a LED chip disposed on the corresponding substrate portion and a package resin body disposed on the corresponding substrate portion to cover the LED chip.

6. The light emitting structure of claim 1, wherein each light emitting element includes a circuit board disposed on the corresponding substrate portion, a LED chip disposed on the circuit board and electrically connected to the circuit board, and a package resin body disposed on the circuit board to cover the LED chip.

7. A light emitting module, comprising:
a carrier unit including at least one carrier body, wherein the at least one carrier body has a mounting portion;
a substrate unit including at least one bendable substrate, wherein the at least one bendable substrate includes a plurality of substrate portions and a plurality of bending portions, the substrate portions are disposed on the mounting portion of the at least one carrier body, and each bending portion is disposed between every two corresponding substrate portions; and
a light emitting unit including a plurality of light emitting groups respectively disposed on the substrate portions, wherein each light emitting group includes at least one light emitting element electrically connected to each corresponding substrate portion.

8. The light emitting module of claim 7, wherein the mounting portion has at least one top mounting surface disposed on the topmost side of the at least one carrier body and a plurality of surrounding mounting surfaces surrounding the periphery of the at least one carrier body, and each surrounding mounting surface is connected to the at least one top mounting surface and obliquely downwardly extended from the at least one top mounting surface, wherein one of the substrate portions is disposed on the at least one top mounting surface, and the other substrate portions are bent along the corresponding bending portion and respectively disposed on the surrounding mounting surfaces.

9. The light emitting module of claim 7, wherein one of the substrate portions is a middle substrate portion, the other substrate portions are surrounding substrate portions surrounding the middle substrate portion, and each surrounding substrate portion is connected to the middle substrate portion and obliquely downwardly extended from the middle substrate portion.

10. The light emitting module of claim 7, wherein each bending portion has at least one cutting groove formed between every two corresponding substrate portions, and the at least one cutting groove is formed on the bottom side of the at least one bendable substrate and faces the at least one carrier body.

11. The light emitting module of claim 7, wherein each bending portion has a plurality of through holes formed between every two corresponding substrate portions, and each through hole passes through the at least one bendable substrate and faces the at least one carrier body.

12. The light emitting module of claim 7, wherein each light emitting element includes a LED chip disposed on the corresponding substrate portion and a package resin body disposed on the corresponding substrate portion to cover the LED chip.

13. The light emitting module of claim 7, wherein each light emitting element includes a circuit board disposed on the corresponding substrate portion, a LED chip disposed on the circuit board and electrically connected to the circuit board, and a package resin body disposed on the circuit board to cover the LED chip.

14. A light emitting device, comprising:
a base unit including at least one electrical connection element disposed on the bottom side thereof;
a carrier unit including at least one carrier body disposed on the top side of the base unit, wherein the at least one carrier body has a mounting portion;
a substrate unit including at least one bendable substrate electrically connected to the at least one electrical connection element, wherein the at least one bendable substrate includes a plurality of substrate portions and a plurality of bending portions, the substrate portions are disposed on the mounting portion of the at least one carrier body, and each bending portion is disposed between every two corresponding substrate portions;
a light emitting unit including a plurality of light emitting groups respectively disposed on the substrate portions, wherein each light emitting group includes at least one light emitting element electrically connected to each corresponding substrate portion; and
a lamp cover unit including a light permitting cover mated with the base unit to protect the substrate unit and the light emitting unit.

15. The light emitting device of claim 14, wherein the mounting portion has at least one top mounting surface disposed on the topmost side of the at least one carrier body and a plurality of surrounding mounting surfaces surrounding the periphery of the at least one carrier body, and each surrounding mounting surface is connected to the at least one top mounting surface and obliquely downwardly extended from the at least one top mounting surface, wherein one of the substrate portions is disposed on the at least one top mounting surface, and the other substrate portions are bent along the corresponding bending portions and respectively disposed on the surrounding mounting surfaces.

16. The light emitting device of claim 14, wherein one of the substrate portions is a middle substrate portion, the other substrate portions are surrounding substrate portions surrounding the middle substrate portion, and each surrounding substrate portion is connected to the middle substrate portion and obliquely downwardly extended from the middle substrate portion.

17. The light emitting device of claim 14, wherein each bending portion has at least one cutting groove formed between every two corresponding substrate portions, and the at least one cutting groove is formed on the bottom side of the at least one bendable substrate and faces the at least one carrier body.

18. The light emitting device of claim 14, wherein each bending portion has a plurality of through holes formed between every two corresponding substrate portions, and each through hole passes through the at least one bendable substrate and faces the at least one carrier body.

19. The light emitting device of claim 14, wherein each light emitting element includes a LED chip disposed on the corresponding substrate portion and a package resin body disposed on the corresponding substrate portion to cover the LED chip.

20. The light emitting device of claim 14, wherein each light emitting element includes a circuit board disposed on the corresponding substrate portion, a LED chip disposed on the circuit board and electrically connected to the circuit board, and a package resin body disposed on the circuit board to cover the LED chip.
